(19) United States
(12) Patent Application Publication
(10) Pub. No.: US 2016/0379913 A1
(43) Pub. Date: Dec. 29, 2016

(54) APPARATUS AND METHOD WITH SELF-ASSEMBLING METAL MICROCHANNELS

(71) Applicant: Alcatel-Lucent Ireland Ltd., Dublin (IE)

(72) Inventors: Brian G. Donnelly, Dublin (IE); Nick Jeffers, Dublin (IE); Jason Stafford, Dublin (IE); Rayhaan Farrelly, Dublin (IE)

(21) Appl. No.: 14/750,160

(22) Filed: Jun. 25, 2015

(51) Int. Cl. H01L 23/473; H01L 23/367; H01L 21/48; C22C 28/00; B23K 1/19; C22C 9/00; C22C 13/00; H01L 23/373; B23K 1/00

(52) U.S. Cl. CPC H01L 23/473; H01L 23/3736; H01L 23/3675; H01L 21/4882; B23K 1/0016; B23K 1/19; C22C 9/00; C22C 13/00; C22C 28/00; B23K 2203/12

(57) ABSTRACT

An apparatus comprising a top substrate having a first surface and a bottom substrate having a second surface facing the first surface. The apparatus comprises a layer of metal located between facing regions of the first and second surfaces and connecting the facing regions to form sidewalls of channels located between the top and bottom substrates, the layer of metal having a different composition than the top and bottom surfaces.

### TECHNICAL FIELD

The invention relates, in general, to an apparatus having microchannels and methods for manufacturing such microchannels.

### BACKGROUND

This section introduces aspects that may help facilitate a better understanding of the inventions. Accordingly, the statements of this section are to be read in this light and are not to be understood as admissions about what is prior art or what is not prior art.

The desire for ever-increasing rates of data communication and computing speed is driving the miniaturization of photonic and electronic integrated circuit devices and their component parts. Miniaturization, however, can be limited by the inefficient removal of the heat as the size of optical and electronic device components are reduced and more densely packed together. Heat removal via coolant circulation in microchannels that are integrated into such devices is a potential solution to the challenge of device thermal management.

### SUMMARY

One embodiment is an apparatus. Some embodiments of the apparatus may comprise a top substrate having a first surface and a bottom substrate having a second surface facing the first surface. Some embodiments of the apparatus may comprise a layer of metal located between facing regions of the first and second surfaces and connecting the facing regions to form sidewalls of channels located between the top and bottom substrates, the layer of metal having a different composition than the top and bottom surfaces.

In some embodiments of the apparatus, one of the surfaces may include copper. In some embodiments of the apparatus, both of the surfaces may include copper. In some embodiments of the apparatus, at least, one of the top and bottom surfaces of the channels may be covered by an oxide.

In some embodiments of the apparatus, the first surface may be a surface of a metal substrate layer of the bottom substrate and the first surface may be covered with a metal oxide layer. In some such embodiments the layer of metal may be a low melt metal alloy layer forming an intermetallic bond with a portion of the metal substrate layer laying under the metal oxide layer. In some such embodiments, the metal substrate layer may be composed of copper. In some such embodiments, the metal substrate layer may be composed of a copper alloy, wherein non-copper atoms do not exceed 10 atomic percent. In some such embodiments, the low melt metal alloy layer may have a melting point value at 1 atmosphere that is in the range from about 60° C. to about 155° C. In some such embodiments, the low melt metal alloy layer may be composed of bismuth, tin and indium.

In some embodiments of the apparatus, the second surface may be a surface of a second metal substrate layer of the top substrate and the second surface may be covered with a second metal oxide layer. In some embodiments, the sidewalls may be composed of a low melt metal alloy layer forming an intermetallic bond with a portion of the second metal substrate layer laying under the second metal oxide layer.

In any such embodiments, the apparatus may be part of a device package that includes device components located on the apparatus such that heat can be removed from the device components via heat transfer to a fluid circulating through the channels. In any such embodiments, a plurality of the channels may form an interconnecting network of looping channels laying in the vicinity of the device components. In any such embodiments, the apparatus may be located on a package substrate of the device package, wherein fluid delivery and fluid receiving conduits located on the package substrate are connected to the channels and to a fluid reservoir located on the package substrate.

Another embodiment is a method. Some embodiments of the method may comprise providing a metal substrate layer having a surface patterned by a metal oxide. Some embodiments of the method may comprise depositing a metal on the patterned surface. Some embodiments of the method may comprise heating the metal substrate layer and the metal such that the metal liquefies and wets portions the surface. Some embodiments of the method may comprise cooling the metal substrate layer to cause the liquefied metal to solidify in a manner that forms channels on the surface.

In some such embodiments of the method, the metal may be a low melt metal alloy. In some such embodiments of the method, the liquefied metal may wet the portions of the surface having metal oxide-free portions of the metal substrate layer exposed on the patterned surface. In some such embodiments of the method, the solidified metal may form an intermetallic bond with the metal oxide-free portion and a low melt metal alloy of the metal. In some such embodiments of the method, the liquefied metal may repel from the portions of the surface having a metal oxide layer on the patterned surface. In some such embodiments of the method, providing the metal substrate layer having the surface patterned by the metal oxide may include patterning a metal oxide layer the metal substrate layer, including masking portions of the metal oxide layer and etching unmasked portions of the metal oxide layer to expose a metal oxide-free portion of the metal substrate layer. Any such embodiments of the method can further include placing a second metal substrate layer on the deposited metal and then, performing the heating and cooling such that the metal bonds the substrates together.

### BRIEF DESCRIPTION OF THE DRAWINGS

The embodiments of the disclosure are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1 presents a membranous plan view of an example apparatus having a microchannel of the present disclosure;

FIG. 2 presents a cross-sectional view of a portion of the example apparatus depicted in FIG. 1 along view line 2-2;

FIG. 3 presents a detailed view of a portion of the example apparatus depicted in FIG. 2;

FIG. 4A presents a flow diagram illustrating an example method of manufacturing an apparatus of the disclosure, such as any of the example apparatus described in the context of FIGS. 1-3;

FIG. 4B presents a flow diagram illustrating other embodiments of an example method of manufacturing an apparatus of the disclosure, such as any of the example apparatus described in the context of FIGS. 1-3;

FIG. 5 presents a cross-sectional view of a portion of an example apparatus similar to that depicted in FIG. 2 at an intermediate stage of manufacture;

FIG. 6 presents a cross-sectional view of a portion of an example apparatus similar to that depicted in FIG. 5 at a later intermediate stage of manufacture;

FIG. 7 presents a cross-sectional view of a portion of an example apparatus similar to that depicted in FIG. 6 at a later intermediate stage of manufacture;

FIG. 8 presents a cross-sectional view of a portion of an example apparatus similar to that depicted in FIG. 7 at a later intermediate stage of manufacture;

FIG. 9 presents a cross-sectional view of a portion of an example apparatus similar to that depicted in FIG. 8 at a later intermediate stage of manufacture;

FIG. 10 presents a cross-sectional view of a portion of an example apparatus similar to that depicted in FIG. 9 at a later intermediate stage of manufacture;

FIG. 11 presents a cross-sectional view of a portion of an example apparatus similar to that depicted in FIG. 9 at a alternative intermediate stage of manufacture;

FIG. 12 presents a cross-sectional view of a portion of an example apparatus similar to that depicted in FIG. 11 at a later intermediate stage of manufacture.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION

The description and drawings merely illustrate the principles of the inventions. It will thus be appreciated that those skilled in the art will be able to devise various arrangements that, although not explicitly described or shown herein, embody the principles of the inventions and are included within its scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

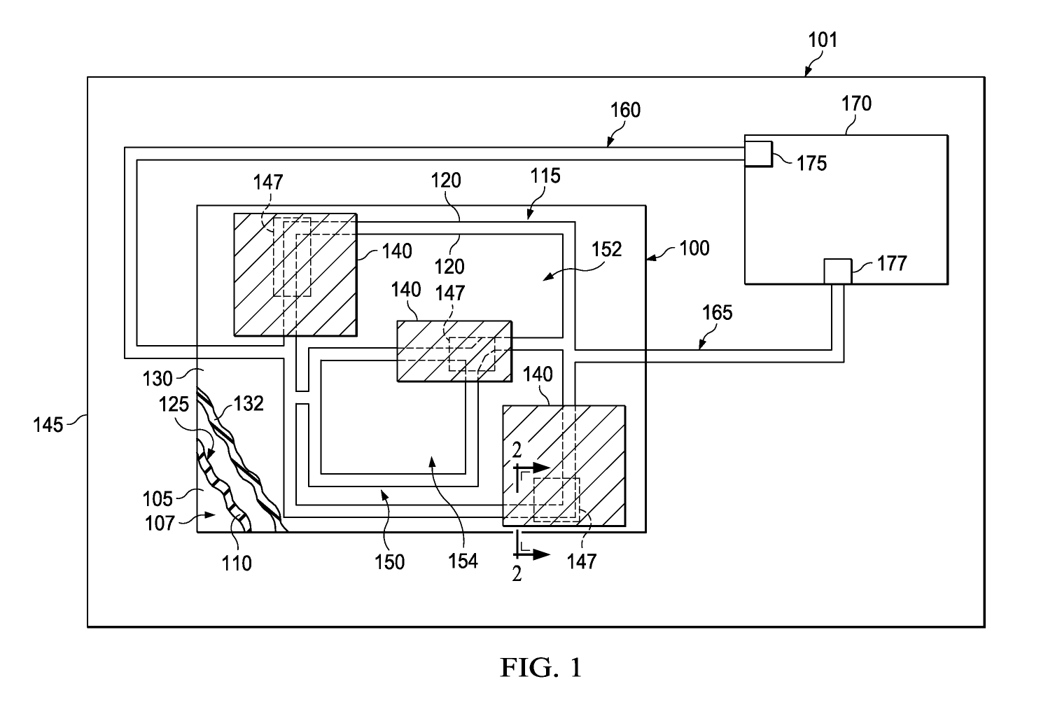

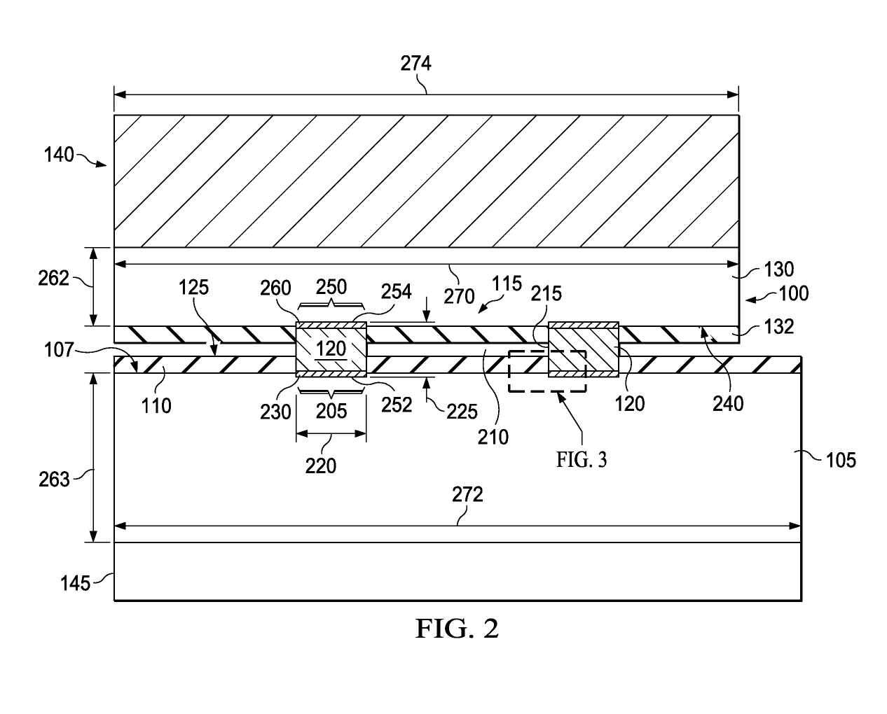

FIG. 1 schematically illustrates an example apparatus 100. The apparatus 100 can be part of a device package 101, e.g., a photonic device package or an electronic device package. FIG. 2 presents a cross-sectional view of a portion of the example apparatus 100 depicted in FIG. 1, along view line 2-2 depicted in FIG. 1.

With continuing reference to FIGS. 1-2, some embodiments of the apparatus may comprise a top substrate (e.g., substrate 130) having a first surface (e.g., surface 240) and a bottom substrate (e.g., substrate 105) having a second surface (e.g., surface 107) facing the first surface. Some embodiments of the apparatus may comprise a layer of metal (e.g., layer 120) located between facing regions of the first and second surfaces and connecting the facing regions to form sidewalls (e.g., sidewall 215) of channels (e.g., channel 115) located between the top and bottom substrates, the layer of metal having a different composition than the top and bottom surfaces.

In some embodiments, one of the surfaces (e.g., one of surface 107 or surface 240) may include copper. In some embodiments, both of the surfaces may include copper. In some embodiments, at least, one of the top and bottom surfaces of the channels may be covered by an oxide (e.g., metal oxide layers 110, 132 inside of the channel duct 210).

In some embodiments, the first surface may be a surface of a metal substrate layer of the bottom substrate (e.g., metal substrate layer 105) and the first surface may be covered with a metal oxide layer (e.g., metal oxide layer 110). In some such embodiments, the layer of metal may be a low melt metal alloy layer (e.g., low melt metal alloy layer 120) forming an intermetallic bond with a portion of the metal substrate layer (e.g., portion 205 of metal substrate layer 105) laying under the metal oxide layer (e.g., metal oxide layer 110). In some such embodiments, the metal substrate layer (e.g., metal substrate layer 105 or metal layer 132) may be composed of copper. In some such embodiments, the metal substrate layer may be composed of a copper alloy, wherein non-copper atoms do not exceed 10 atomic percent. In some such embodiments, the low melt metal alloy layer may have a melting point value at 1 atmosphere that is in the range from about 60° C. to about 155° C. In some such embodiments, the low melt metal alloy layer may be composed of bismuth, tin and indium.

In some embodiments, the second surface (e.g., surface 240) may be a surface of a second metal substrate layer (e.g., metal substrate layer 130) of the top substrate and the second surface may be covered with a second metal oxide layer (e.g., metal oxide layer 132). In some embodiments, the sidewalls (e.g., sidewall 215) may be composed of a low melt metal alloy layer forming an intermetallic bond with a portion of the second metal substrate layer laying under the second metal oxide layer (e.g., portion 250 of metal substrate layer 130).

In any such some embodiments, the apparatus 100 may be part of a device package (e.g., package 101) that includes device components (e.g., device components 140). In some embodiments one or both of the top substrate and bottom substrate can be chip substrates containing the device components, whereby the device package is or includes a multichip device and the channels 115 are configured as the cooling channels located between the chip substrates. In any such embodiments, the device components can be located on the apparatus such that heat can be removed from the device components via heat transfer to a fluid (e.g., a coolant fluid such as water) circulating through the channels (e.g., channels 115). In any such embodiments, a plurality of the channels may form an interconnecting network of looping channels (e.g., loop channel loops 150, 152, 154) lying in the vicinity of the device components. In any such embodiments, the apparatus may be located on a package substrate (e.g., package substrate 145) of the device package, wherein fluid delivery and fluid receiving conduits (e.g., conduits 160, 165) located on the package substrate are connected to the channels and to a fluid reservoir (e.g., reservoir 170) located on the package substrate.

Various embodiments may benefit from microchannels formed from a metal composed of a low melt metal alloy that self-assembles and covalently bonds to treated portions of a metal surface. Selected portions of the metal surface may be treated to provide a low energy surface such that a low melt metal alloy, when in a liquid, melted state, wets the low energy metal surface and thereby self-assembles to form the walls of a microchannel on the treated portions. The liquid low melt metal alloy may be repelled from, and may not covalently bond to, untreated portions of the oxidized metal surface which has a higher surface energy than the treated portions. Upon solidifying, the low melt metal alloy may form a covalent bond (e.g., a covalent intermetallic bond in some embodiments) to the treated portion of the metal surface. Low cost and simplicity of formation of complex networks of microchannels can facilitate usage of microchannels in thermal management of different heat-generating components, e.g., in mass-produced photonic and electronic device packages.

Some embodiments of the apparatus 101 comprise a metal substrate layer 105 having a surface 107 with a metal oxide layer 110 thereon and one or a plurality of microchannels 115, on the surface 107. The microchannel 115 includes a low melt metal alloy layer 120, or a plurality of low melt metal alloy layers 120, forming a bond (e.g., an intermetallic bond in some embodiments) with a portion 205 of the metal substrate layer 105 laying under the metal oxide layer 110.

In some embodiments, the microchannel 115 has a hydraulic diameter (d_{H}) of about 2 millimeter or less, where d_{H} is defined by 4·A/p where A equals the cross-sectional area of a channel duct 210 of the microchannel 115, and p equals the wetted perimeter of the duct 210. For instance, in some embodiments, the microchannel 115, or microchannels, of the apparatus 100, if or when fully wetted by a fluid (e.g., a liquid coolant such as water) in the duct 210 have a hydraulic diameter of about 2 millimeter or less, and in some embodiments, about 1000 microns or less, about 100 microns or less, and in some embodiments, about 10 microns or less, and in some embodiments, about 1 micron or less.

In some embodiments, low melt metal alloy layers 120 define the walls of the microchannels 115 and can be considered the same as a channel wall. In such embodiments, the low melt metal alloy layers 120 provide sidewalls 215 of the microchannel duct 210. In some embodiments, one or more of the dimensions of the melt alloy layers that define the microchannel walls are millimeter or sub-millimeter in size. For instance, in some embodiments, one or both of the thickness 220 or height 225 of the layers 120 are about 1 millimeter or less, and in some embodiments, about 100 microns or less, and in some embodiments, about 10 microns or less, and in some embodiments, about 1 micron or less.

The dimensions of the microchannels 115 and the layers 120 can be advantageously controlled to within narrow tolerance limits. For instance, in some embodiments, the hydraulic diameter of the microchannel 115 and the dimensions of the layers 120 defining the channel walls can be manufactured to a precise target value with a variation of ±1 percent or less, and in some embodiments, ±0.1 percent or less. In turn, the accurate formation microchannels 115 and layers 120 with precise target dimensions facilitates forming a network of the microchannels 115 can be made with high reproducible thermal management properties. The ability to accurately form the same dimensions of microchannels 115 and the layers 120 defining the channel walls from one batch fabrication process to the next can be a significant advantage over other fabrication processes, such as certain three-dimensional printing procedures or laser sintering processes which can produce channel walls of variable thickness or height.

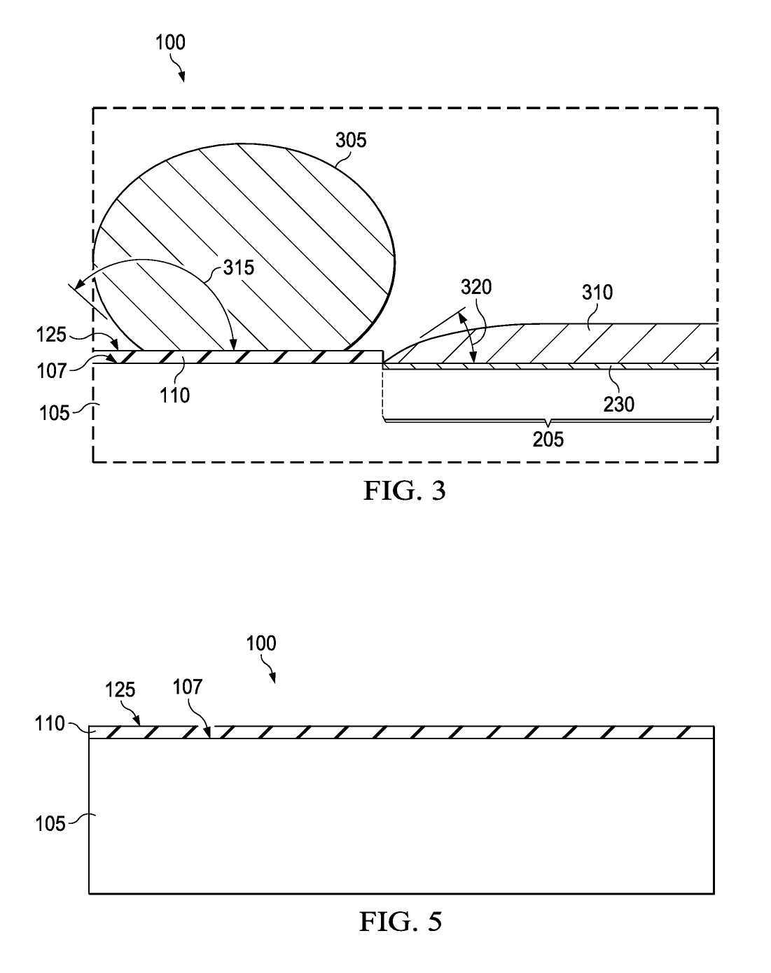

Some embodiments of the metal substrate layer 105 may be composed of or formed of a metal that provides a higher energy surface 107 than the surface energy of the metal oxide layer surface 125, with respect to a liquid state of the low melt metal alloy, and, that may form an intermetallic bond with the low melt metal alloy. The is illustrated in FIG. 3 which shows a detailed view of a portion of the example apparatus 100 depicted in FIG. 2 with two melted droplets 305, 310 of the low melt metal alloy on the metal oxide layer surface 125 and a portion 205 of the metal substrate layer 105 whose surface 107 is substantially free of the oxide layer 110.

The liquid low melt metal alloy droplet 305 located on the comparatively lower energy surface 125 of the metal oxide layer 110 has a high contact angle 315 (e.g., a contact angle 315 in a range from about 90 degrees to about 180 degrees in some embodiments) and therefore does not wet the surface 125. Additionally, the liquid low melt metal alloy droplet 305 does not bond (e.g., intermetallically bond in some embodiments) with the surface 125 of the metal oxide layer 110. Consequently, the droplet 305 can readily roll off of, or be repelled away from (e.g., automatically move off), the metal oxide layer surface 125.

The liquid low melt metal alloy droplet 310 located on the comparatively higher energy surface 107 of the portion 205 of metal substrate layer 105 that has a low contact angle 320 (e.g., a contact angle 320 in a range from about 0 degrees to about 90 degrees in some embodiments) and therefore wets the surface 107. Additionally, the melted low melt metal alloy droplet 310 bonds (e.g., intermetallically bonds in some embodiments) with the surface 107 of the metal substrate layer 105. Consequently, the droplet 315 can spread out on and covalently adhere or bond to the metal substrate layer surface 107.

Additionally, if the liquid low melt metal alloy droplet 305 on the metal oxide layer surface 125 rolls in the direction of the metal substrate layer surface 107, then the two drops 305, 310 can coalesce to form a larger combined droplet that covalently adheres or bonds to the metal substrate layer surface 107. In sufficient quantity, the liquid low melt metal alloy forms the low melt metal alloy layer 120 that may be bonded (e.g., intermetallically bonded in some embodiments) to the portion 205 of the metal substrate layer 105.

In some embodiments, the metal substrate layer 105 may be composed of or formed of copper. That is, the metal substrate layer 105 contains only trace amount of non-copper atoms not exceeding about 1 atomic percent of the layer 105, and that in some embodiments, does not exceed about 0.1 atomic percent.

In some embodiments, the metal substrate layer 105 may be composed of or formed of a copper alloy, wherein the non-copper atoms do not exceed 10 atomic percent of the layer 105 and in some embodiments, do not exceed about 0.1 atomic percent. For instance, in some embodiments the non-copper atoms may be included to e.g., increase the corrosion resistance or mechanical strength of the layer 105. Non-limiting examples of non-copper atoms in the metal substrate layer 105 when composed of a copper alloy include nickel or zinc.

In some embodiments, the metal oxide layer 110 on the metal substrate layer 105 may be an oxide of the same metal elements of which the metal substrate layer 105 is composed. For instance, when the metal substrate layer 105 is composed of or formed of copper, then the metal oxide layer 110 may be composed of or formed of copper oxides (e.g., CuO and/or CuO₂). Or, when the metal substrate layer 105 is composed of or formed of a copper alloy, then the metal oxide layer 110 may be composed of or formed of oxides of the copper alloy. In some embodiments, the metal oxide layer can include one or more different metal elements, which differ from the metal elements of metal substrate layer 105. Some such embodiments may provide an additional way to adjust the surface energy of the metal oxide layer 110 surface 125 to a particular value, e.g., so as to better repel a particular liquid low melt metal alloy composition.

As illustrated in FIGS. 2 and 3, in some embodiments an intermetallic compound region 230 may be located in-between the portion 205 of the metal substrate layer 105 not having a metal oxide layer 110 thereon and the low melt metal alloy layer 120. The intermetallic compound region 230 includes metal atoms of the metal substrate layer 105 and metal atoms of the low melt metal alloy layer 120 that are covalently bonded to each other. In some embodiments as part of forming the low melt metal alloy layer 120 the apparatus 100 may be heated to a temperature above the melting temperature of the low melt metal alloy such that the portion 205 of the metal substrate layer 105 is also liquefied facilitating bonding, and in some embodiments intermetallic bonding, to occur. In some embodiments, after cooling, within the portion 205, the intermetallic compound region 230 can include dendrites, familiar to those skilled in the art, containing the metal of the low metal alloy layer 120 that pierce into the metal of the metal substrate layer 105.

Embodiments of the low melt alloy layer 120 can include metals that have a melting point in a target range and that can form bonds (e.g., intermetallic bonds in some embodiments) to the portion 205 of the metal substrate layer 105 when liquefied. To maintain the structural dimensions of the microchannels 115, it is desirable for the melting point of the low melt alloy layer 120 be above the operating temperature of any the optical or electronic device components, and, for the melting point to be below a temperature that may damage the component. For instance, some embodiments of the low melt alloy layer, at 1 atmosphere of pressure, may have a melting point value that is in the range from about 60° C. to about 155° C. For instance, in some embodiments, the composition of the low melt alloy is selected or adjusted to have a melting point that is at least about 5° C. higher than the operating temperature range of a device component being thermally managed. For instance, if the device component is a central processing unit operating at a temperature of 110° C., then, in some embodiments, the low melt alloy layer 120 preferably has a melting temperature of at least about 115° C.

In some embodiments, to facilitate heat transfer, the low melt metal alloy layer 120 is selected have a thermal conductivity that is at least 25 percent of the thermal conductivity of metal substrate layer 110. For example, consider a device embodiment where the metal substrate layer 110 is composed of pure copper (e.g., at least about 99.9 atomic percent copper) and has a thermal conductivity of the metal substrate layer can equal about 385 W·m⁻¹·K⁻¹. In some such embodiments, the low melt metal alloy layer 120 can have a thermal conductivity of at least about 96 W·m⁻¹·K⁻¹.

In some embodiments, the low melt metal alloy layer 120 includes an alloy of at least two of, or some in embodiments, at least all three of, bismuth, tin and indium to provide a target melting point value falling in the above-described range as well as facilitate boning (e.g., intermetallic bonding in some embodiments) to a copper metal substrate layer 110. In some embodiments, for instance, the low melt metal alloy is composed of about 32:17:51 Bi:Sn:In to provide a low melt metal alloy, sometimes referred to as Field's metal, with a melting point in the range of about 60 to 65° C. In some embodiments, for instance, the low melt metal alloy is composed of about 17:50:33 Bi:Sn:In to provide a low melt metal alloy, with a melting point in a range of about 110 to 120° C. In some embodiments the low melt metal alloy may be known solders.

In still other embodiments, other metal elements can be included in combination with each other or with one or more of bismuth, tin and indium to provide a low melt metal alloy with the desired mechanical strength, melting point and bonding characteristics. Non-limiting examples of such metal elements include silver, antimony, cadmium and lead. In some embodiments the low melt metal alloy layer 120 is lead-free. In some embodiments, the low melt metal alloy layer 120 is cadmium-free.

As further illustrated in FIGS. 1 and 2, to enclose the microchannel 115, some embodiments of the apparatus 100 can further include a second metal substrate layer 130 having a second surface 240 with a second metal oxide layer 132 thereon. The microchannel 115 or microchannels 115 may be located on the second metal substrate layer surface 240. The low melt metal alloy layer 120, defining a wall of the microchannel 115, forms another second, bond (e.g., intermetallic bond in some embodiments) with a portion 250 of the second metal substrate layer 130 lying under the second metal oxide layer 132.

As illustrated in FIGS. 2 and 3 in some embodiments, the low melt metal alloy layer 120 may be located between the portions 205, 250 of the metal substrate layer 105 and a second metal substrate layer 132 that are not oxidized, e.g., that do not have the metal oxide layers 110, 132.

As further illustrated in FIG. 2, for some embodiments, one end 252 of the low melt metal alloy layer 120 may contact the portion 205 of the first metal substrate layer 105, that may include the first intermetallic compound region 230, and the opposite end 254 of the layer 120 may contact the portion 250 of the second metal substrate layer 130 that may include a second intermetallic compound region 260. Similar to the first intermetallic region 230, the second intermetallic region 260 may include metal atoms of the second metal substrate layer 130 and metal atoms of the low melt metal alloy layer 120 that are covalently bonded to each other.

In some embodiments, to simplify the manufacturing process and reduce material costs, the second metal substrate layer 130 and second metal oxide layer 132 may have the same compositions as the first metal substrate layer 105 and second metal oxide layer 110, respectively. However, in other embodiments, the second metal substrate layer 130 and second metal oxide layer 132 may have different compositions than their respective first metal layer and first metal oxide layer counterparts. In some embodiments, to simplify the manufacturing process, the second metal substrate layer 130 and second metal oxide layer 132 may have the same dimensions as the first metal substrate layer 105 and first metal oxide layer 110, respectively. In other embodiments, however, one or more of the dimensions may be different their respective first metal layer and first metal oxide layer counterpart. As non-limiting examples, to facilitate heat transfer from an overlying device component 140, the thickness 262 of the second metal substrate layer 130 may be less than the thickness 263 of the first metal substrate layer 110. For instance, when the first metal substrate layer thickness 263 equals about 10 or 1 millimeter, the second metal substrate layer thickness 262 may equal about 10 percent or about 25 percent of the first metal substrate layer thickness 262. Or, to reduce material costs, the length or width (e.g., represented by dimension 270 in FIG. 2) of the second metal substrate layer 130 may be less than the corresponding length or width (e.g., represented by a dimension 272 in FIG. 2) of the first metal substrate layer 105. In other embodiments, the length or width (e.g., represented by dimension 270 in FIG. 2) of the second metal substrate layer 130 may be greater than the corresponding length or width of the first metal substrate layer 105. For instance, the length or width (e.g., dimension 270) of the second metal substrate layer 130 can be reduced or increased to match the length or width (e.g., dimension 274) of an overlying device component 140 thermally managed by the apparatus 100.

As illustrated in FIG. 1, in some embodiments, the apparatus 100 may be part of a device package 101 such as a photonic device package or electronic device package. As illustrated, the device package 101 can include a plurality of device components 140 located on a package substrate 145 (e.g., a circuit board) and in some embodiments on the apparatus 100. Non-limiting example device components 140 include heat-generating components such as light emitting laser diodes, central processing units or other active components or passive component such as resistors. In other embodiments, one or more of the device components 140 may not generate substantial amounts of heat, but, have operating characteristics that are sensitive to temperature. In some embodiments, for example, each of the device components 140 may correspond to a laser diode, and, the small spacing between such laser diodes, where without proper thermal management such as provided by the apparatus 100, could have undesirable shifts in the wavelength of the light emitted from the laser diode due to thermal crosstalk between the lasers diodes.

As also illustrated in FIG. 1, to facilitate precise cooling, at least some the device components 140 of the device package 101 may be located on the apparatus 100 such that heat can be removed from the components 140 via heat transfer to a fluid circulating through the microchannel 115. In some embodiments, to increase the efficiency of heat transfer, hot spots 147 of the components 140 may be located in the vicinity of at least one microchannel 115. Hot-spots 147 may correspond to portions of device component 140 have a higher temperature that any other portion of the component 140. For instance, a microchannel 115 may lie directly below a known hot-spot 147.

In some embodiments, to facilitate precise cooling, the apparatus 100 can include a plurality of the microchannels 115 that form an interconnecting network of looping channels (e.g., interconnecting channel loops 150, 152, 154) on the metal substrate layer 105. The network of interconnecting microchannel loops 150, 152, 154 can lie on specific areas of the metal substrate layer 105, or below the second metal layer 240, such that specific amounts of heat are removed from the overlying device components 140 while operating. For instance, to optimize cooling, in some embodiments, the microchannels 115 can be formed so as to intersect, bend, or loop in the vicinity of, and in some embodiments lie directly below, known hot-spot locations 147 on a particular device component 140.

As further illustrated in FIG. 1, in some embodiments of the device package 101, the microchannels 115 of the apparatus 100 can be connected to fluid (e.g., liquid) delivery and receiving conduits 160, 165, e.g., located on the package substrate 145. In some embodiments the conduits 160, 165 may be connected to a fluid (e.g., liquid) reservoir 170 that is also located on the package substrate 145. The reservoir 170 is configured to hold a fluid, such as a liquid such as water, or other liquid coolant, that may be circulated through microchannels 115, e.g., through one or more pumps 175, 177 coupled to the conducts 160, 165 and reservoir 170.

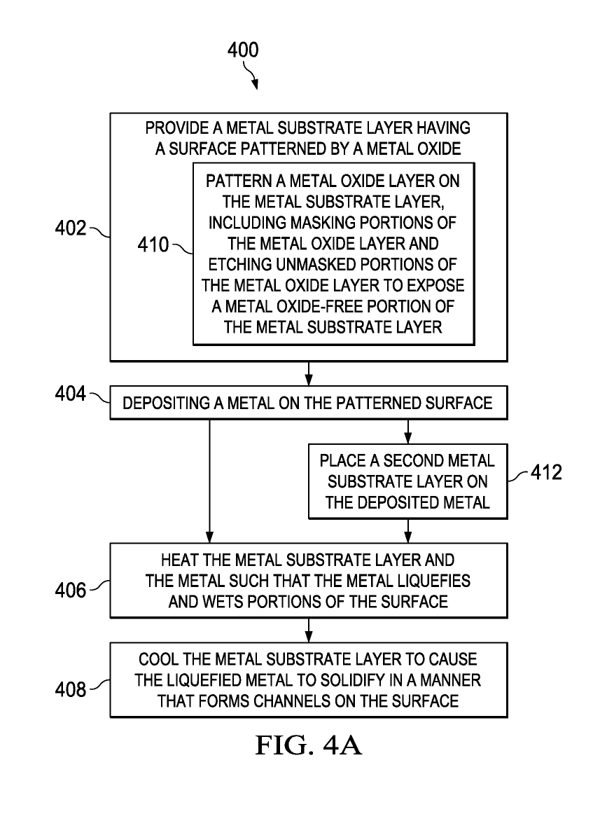

FIG. 4A presents a flow diagram of an example method 400. Some embodiments of the method may comprise a step 402 of providing a metal substrate layer having a surface patterned by a metal oxide. Some embodiments of the method may comprise a step 404 of depositing a metal on the patterned surface. Some embodiments of the method may comprise a step 406 of heating the metal substrate layer and the metal such that the metal liquefies and wets portions the surface. Some embodiments of the method may comprise a step 408 of cooling the metal substrate layer to cause the liquefied metal to solidify in a manner that forms channels on the surface.

In some such embodiments of the method, the metal may be a low melt metal alloy. In some such embodiments of the method, the liquefied metal may wet the portions of the surface having metal oxide-free portions of the metal substrate layer exposed on the patterned surface. In some such embodiments of the method, the solidified metal may form a bond (e.g., an intermetallic bond in some embodiments) with the metal oxide-free portion and a low melt metal alloy of the metal. In some such embodiments of the method, the liquefied metal may repel from the portions of the surface having a metal oxide layer on the patterned surface. In some such embodiments of the method, providing the metal substrate layer having the surface patterned by the metal oxide (step 402) may include a step 410 of patterning a metal oxide layer the metal substrate layer, including masking portions of the metal oxide layer and etching unmasked portions of the metal oxide layer to expose a metal oxide-free portion of the metal substrate layer. Any such embodiments of the method can further include a step 412 of placing a second metal substrate layer on the deposited metal and then, performing the heating and cooling (steps 406 and 408) such that the metal bonds the substrates together.

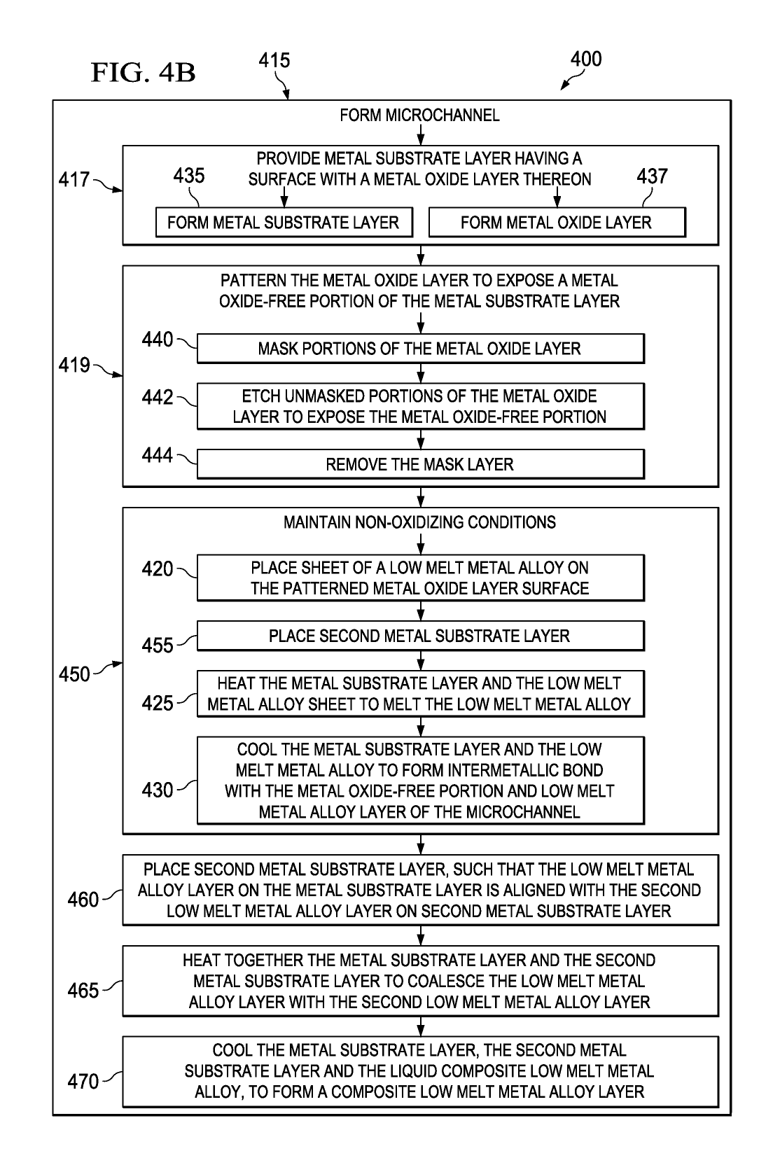

FIG. 4B presents a flow diagram to illustrate another embodiment of the method 400, such as a method of manufacturing any of the example apparatuses 100 described in the context of FIGS. 1-3. To illustrate aspects of the method 400, FIGS. 5-10 present cross-sectional views of a portion of an example apparatus, similar to that depicted in FIG. 2, at various intermediate stages of manufacture.

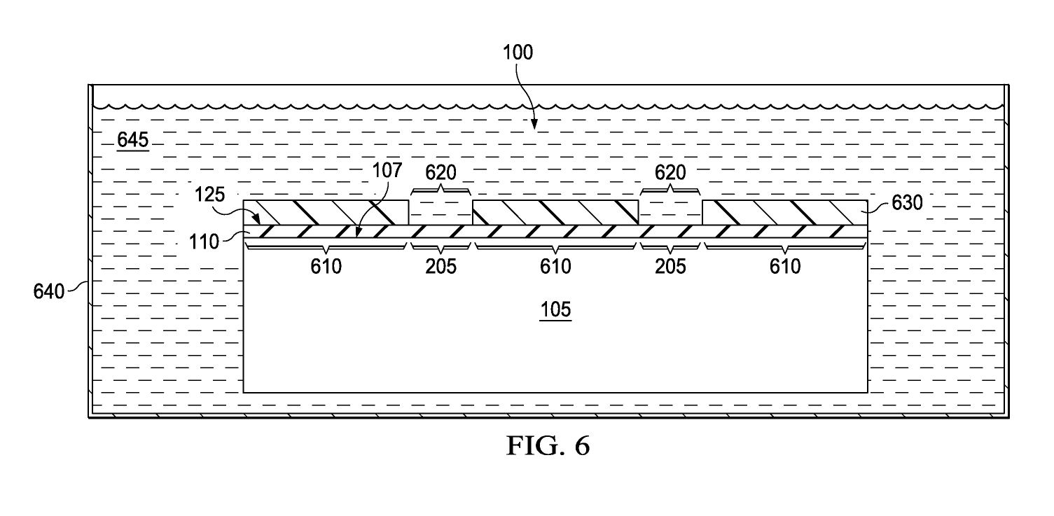

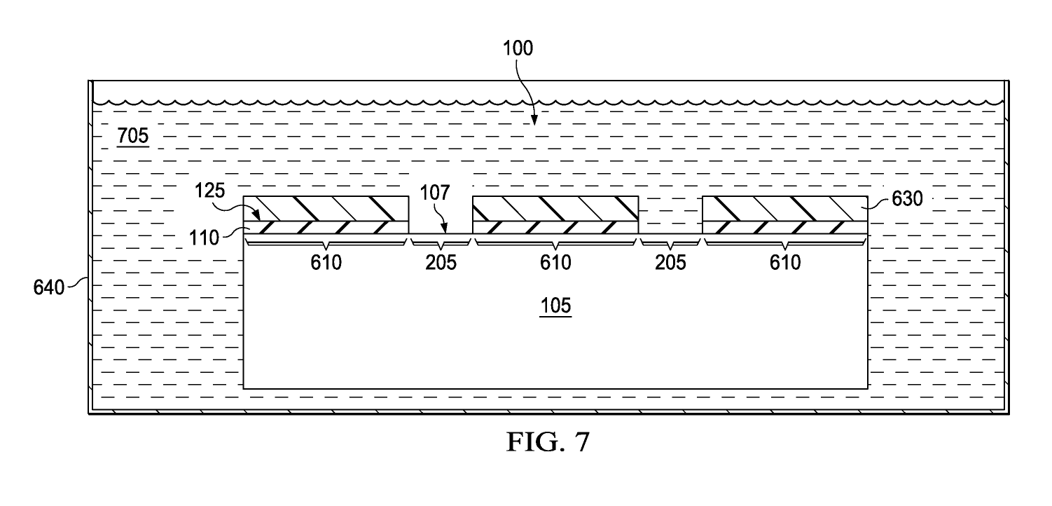

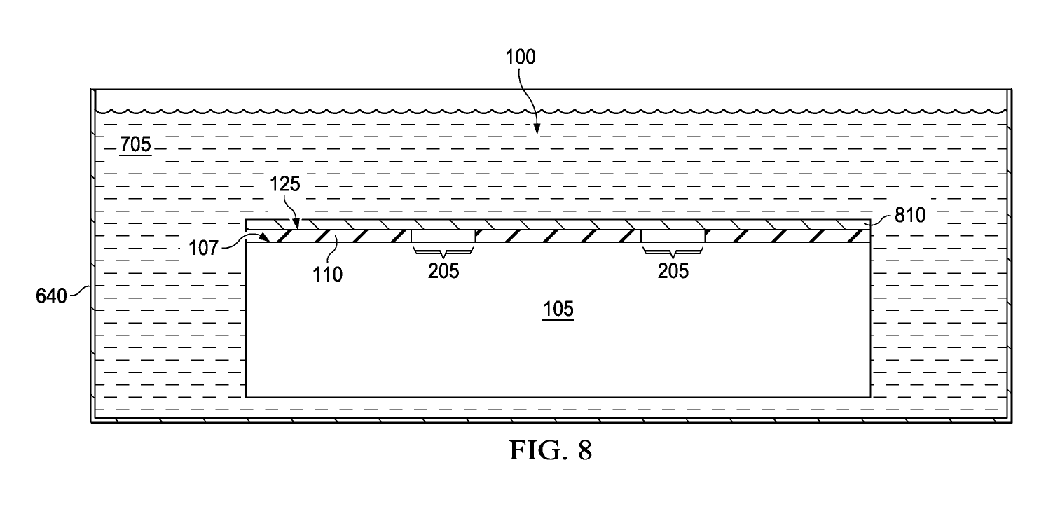

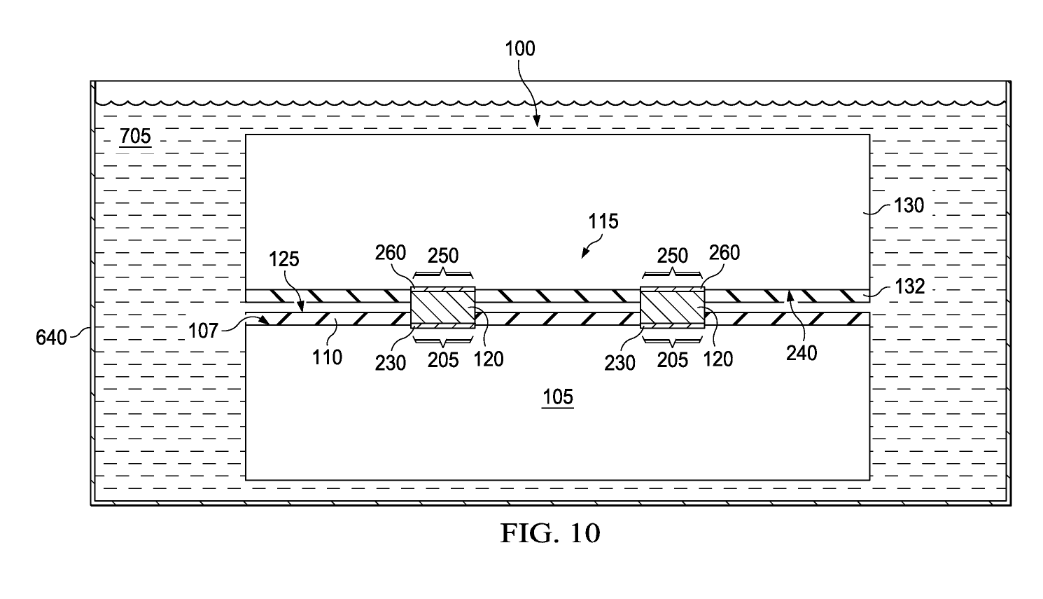

With continuing reference to FIGS. 1-10 throughout, as illustrated in FIG. 4B, embodiments of the method may comprise, a step 415 of forming a microchannel 115. In some embodiments, forming the microchannel 115 (step 415) may include a step 417 of providing a metal substrate layer 105 having a surface 107 with a metal oxide layer 110 thereon (FIG. 5). In some embodiments, forming the microchannel 115 (step 415) may include a step 419 of patterning the metal oxide layer 110 to expose a metal oxide-free portion 205 of the metal substrate layer 105 (FIGS. 6-7). In some embodiments, forming the microchannel 115 (step 415) may include a step 420 of placing a sheet of a low melt metal alloy 910 on the patterned metal oxide layer surface 125 (e.g., sheet 810 FIG. 8). In some embodiments, forming the microchannel 115 (step 415) may include a step 425 of heating the metal substrate layer 105 and the low melt metal alloy sheet 910 sufficiently to melt the low melt metal alloy sheet. Under such conditions, a liquid form of the low melt metal alloy may wet the exposed metal oxide-free portion 205 and may repel from the metal oxide layer surface 125. In some embodiments, forming the microchannel 115 (step 415) may include a step 430 of cooling the metal substrate layer and the low melt metal alloy. Under some such conditions, a solid form of low melt metal alloy may form a bond (e.g., an intermetallic bond in some embodiments) with the metal oxide-free portion 205 and may forms a low melt metal alloy layer 120 of the microchannel 115 (FIG. 10).

In some embodiments of the method, the metal substrate layer 105 with a metal oxide layer 110 may be obtained from commercial sources. In other embodiments, however, it may be advantageous to form one or both of the metal substrate layer 105 and the metal oxide layer 110 to particular specifications. That is, in some embodiments, providing the metal substrate layer 105 and metal oxide layer 110 in step 417 may include a step 435 of forming the metal substrate layer and a step 437 of forming the metal oxide layer 110 on the surface 107 of the metal substrate layer 105.

For example, in some embodiments of the method, a metal sheet laminated onto a non-conductive substrate such as a circuit board package substrate 145 may be patterned using lithographic and etching procedures to form the metal substrate layer 105. In other embodiments, chemical or physical deposition procedures familiar to those skilled in the art may be used to form the metal substrate layer 105 of the substrate 145. In other embodiment, a separate metal sheet may be pressed and/or cut to form the metal substrate layer 105 of the desired thickness, width and length.

In some embodiments of the method, the metal oxide layer 110 may be a native metal oxide layer that is formed by exposing the metal substrate surface 107 to an ambient air environment surrounding the device 101. In other embodiments, to more precisely control the thickness and composition of the metal oxide layer 110, the layer 110 may be formed in a controlled environment such as in a chemical vapor deposition chamber. Having a metal oxide layer 110 of a precisely controlled thickness and composition may, e.g., facilitate the rapid and precise patterning of the layer 110 to expose the portion 205 of the metal substrate layer 105, or, facilitate better control of the extent to which the low melt metal alloy layers 120 are embedded in the oxide layer 110. The control of such properties, in turn, may facilitate precise adjustments of the layers 120 defining the channel wall dimensions, mechanical strength and/or the thermal conduction of heat from the duct 210, through the melt alloy layers 120 and into the ambient environment surrounding the device 101.

In some embodiments of the method, patterning the metal oxide layer in step 419 may includes a step 440 of masking portions 610 of the metal oxide layer 110 (FIG. 6). Patterning the metal oxide layer in step 419 may include a step 442 of etching unmasked portions 620 of the metal oxide layer 110 to expose the metal oxide-free portion 205 of the metal substrate layer 105. In some embodiments, masking portions of the metal oxide layer 110 in step 440 may include placing one or more mask layers 630 on the metal oxide layer surface 125 such that unmasked portions 620 of the metal oxide layer 110 overlay target locations of the low metal alloy layer 120. In some embodiments, the mask layer 630 may be composed of polytetrafluoroethylene, or similar acid resistant fluoropolymer.

In some embodiments of the method, etching the unmasked portions of the metal oxide layer (step 442) may include exposing the unmasked portions to a concentrated aqueous strong acid solution. For instance, the metal substrate layer 105 with the masked metal oxide layer 110 may be placed in a bath 640 containing an aqueous strong acid solution 645 such as HCl (e.g., about 0.5 to 5 M HCl for about 1 to 20 minutes, and about 2 M HCl for about 5 to 10 minutes, in some embodiments). In some embodiments, after the etching step at least 99 percent, and in some embodiments, 99.9 percent, of the surface area of the exposed portion 205 is free of metal oxide.

Patterning the metal oxide layer in step 419 may include a step 444 of removing the mask layer 630 after etching the unmasked portions of the metal oxide layer in step 442.

In some embodiments of the method, in step 450, the metal substrate layer 105 and overlying patterned oxide layer 110 may be maintained in non-oxidizing conditions (FIG. 7). Subsequent steps, such placing the sheet of a low melt metal alloy 610 (step 420), heating the metal substrate layer 105 and the low melt metal alloy sheet 910 (step 425), and cooling the metal substrate layer and the low melt metal alloy (step 430), may preferably be performed under non-oxidizing conditions (step 450) to prevent the metal oxide layer 110 from reforming on the exposed portions 205 of the metal substrate layer 110 and interfering with the formation of bonds (e.g., intermetallic bonds in some embodiments) between the low melt allow and metal substrate layer 105.

For instance, in some embodiments of the method, as part of step 450, the metal substrate layer 105 and overlying patterned oxide layer 110 may be kept in a mild aqueous strong acid solution 705 during steps 420, 425 and 430. The concentration of mild aqueous strong acid solution 705 may be adjusted so as prevent further removal of remaining portions of metal oxide layer 110 during the time taken to perform steps 420, 425 and 430. For instance, as part of step 450, the metal substrate layer 105 and overlying patterned oxide layer 110 may be retained in the bath 640 of an aqueous mild acid solution 705 such as HCl (e.g., about 0.01 to 0.2 M HCl, and about 0.1 M HCl, in some embodiments). In other embodiments however, as part of step 450, the metal substrate layer 105 and overlying patterned oxide layer 110 may be maintained in a non-oxygen environment, such as in a chamber 640 holding a vacuum or inert atmosphere, during steps 420, 425 and 430.

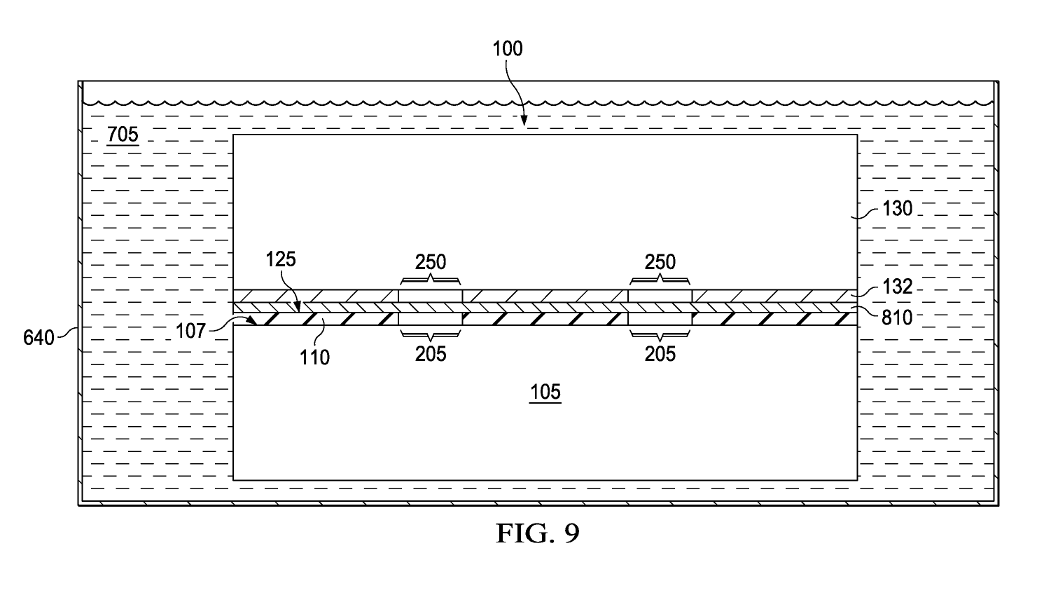

Some embodiments of the method may further include a step 455 of placing a second metal substrate layer 130, with a second patterned metal oxide layer 132 thereon, on the patterned metal oxide layer surface 125 of the first metal substrate layer 110 (FIG. 9). In some embodiments, placing in step 455 may be such that the exposed metal oxide-free portion 205 of the metal substrate layer 105 is aligned with an unmasked exposed metal oxide-free portion 250 of the second metal substrate layer and the sheet of a low melt metal alloy 810 is located between the patterned metal oxide layer 110 and the second patterned metal oxide layer 132. Any of the above-described procedures to patterning the metal oxide layer 110 may also be applied to pattern the second metal oxide layer 132.

In some embodiments, the step 455 of placing the second metal substrate layer 130 may be performed after placing the low melt metal alloy sheet 810 (step 420) and during the maintenance of non-oxidizing conditions (step 450) but before the heating and cooling steps 425 and 430. As illustrated in FIG. 10, after the completion of step 430 the apparatus 100 similar to the apparatus 100 depicted in FIG. 2 is produced.

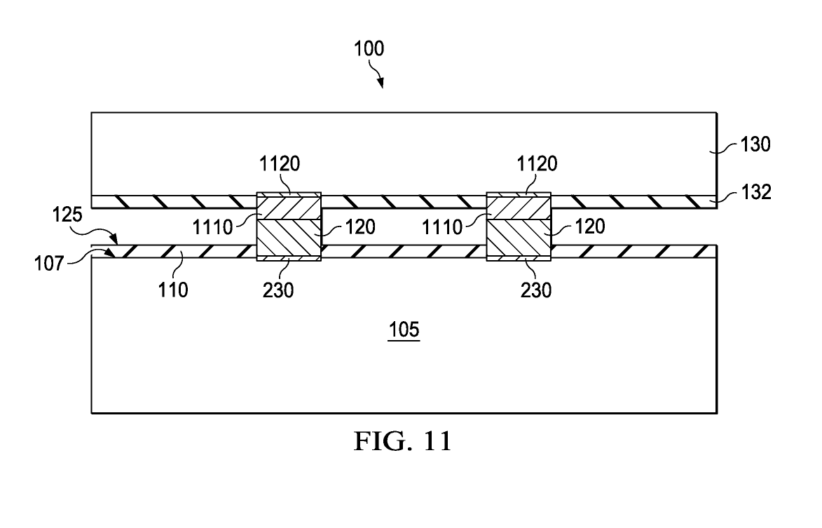

In some alternative embodiments of the method, the second metal substrate layer 130 may be placed in step 460, on the first metal substrate layer 105 after the completion of steps 420, 425 and 430 which may be performed separately on the metal substrate layer 110 and the second metal substrate layer 130. As illustrated in FIG. 11, the first metal substrate layer 110 may include the low melt metal alloy layer 120 thereon and bonding (e.g., intermetallic bonding in intermetallic compound region 230 in some embodiments) with the metal oxide-free portion 205. Similarly, the second metal substrate layer 130 may include a second low melt metal alloy layer 1110 thereon and second bonding (e.g., intermetallic bonding in second intermetallic compound region 1120 in some embodiments) to a metal oxide-free portion 1120 of the second metal substrate layer 130. As part of step 460, the second metal substrate layer 130, with the second patterned metal oxide layer 132 thereon, may be placed such that the low melt metal alloy layer 120 is aligned with the second low melt metal alloy layer 1110.

Some such embodiments of the method may include, in step 465, heating together the metal substrate layer 105 with the low melt metal alloy layer 120 thereon and the second metal substrate layer 130 with the second low melt metal alloy layer 1110 such that liquid forms of the low melt metal alloy layer 120 and the second the low melt metal alloy layer 1110 coalesce to form a liquid composite low melt metal alloy.

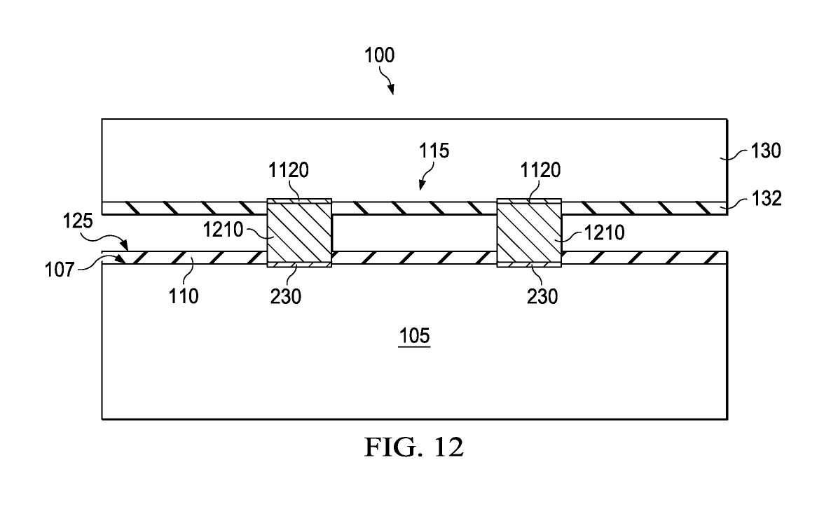

Some such embodiments of the method may include, in step 470, cooling the metal substrate layer 105, the second metal substrate layer 130 and the liquid composite low melt metal alloy, wherein a solid form of composite low melt metal alloy forms a composite low melt metal alloy layer 1210 of the microchannel 115 which includes the low melt metal alloy of the low melt metal alloy layer 120 coalesced therein (FIG. 12).

In some embodiments, the steps 460, 465 and 470 may not need to be performed while maintaining non-oxidizing conditions (step 450) because, e.g., the low melt metal alloy and second low melt metal alloy are already bonded (e.g., intermetallically bonded in some embodiments) to the respective metal oxide free portions 230, 260 of the respective first and second metal substrate layers 105, 130.

Although the present disclosure has been described in detail, those skilled in the art should understand that they can make various changes, substitutions and alterations herein without departing from the scope of the invention.

1. An apparatus, comprising:
a top substrate having a first surface;
a bottom substrate having a second surface facing the first surface; and
a layer of metal located between facing regions of the first and second surfaces and connecting said facing regions to form sidewalls of channels located between the top and bottom substrates, the layer of metal having a different composition than the top and bottom surfaces.

2. The apparatus of claim 1, wherein one of the surfaces includes copper.

3. The apparatus of claim 1, wherein both of the surfaces includes copper.

4. The apparatus of claim 1, wherein, at least, one of the top and bottom surfaces of the channels is covered by an oxide.

5. The apparatus of claim 1, wherein:
the first surface is a surface of a metal substrate layer of the bottom substrate and the first surface is covered with a metal oxide layer; and
the layer of metal is a low melt metal alloy layer forming an intermetallic bond with a portion of the metal substrate layer laying under the metal oxide layer.

6. The apparatus of claim 5, wherein the metal substrate layer is composed of copper.

7. The apparatus of claim 5, wherein the metal substrate layer is composed of a copper alloy, wherein non-copper atoms do not exceed 10 atomic percent.

8. The apparatus of claim 5, wherein the low melt metal alloy layer has a melting point value at 1 atmosphere that is in the range from about 60° C. to about 155° C.

9. The apparatus of claim 5, wherein the low melt metal alloy layer is composed of bismuth, tin and indium.

10. The apparatus of claim 1, wherein:
the second surface is a surface of a second metal substrate layer of the top substrate and the second surface is covered with a second metal oxide layer; and
the sidewalls are composed of a low melt metal alloy layer forming an intermetallic bond with a portion of the second metal substrate layer laying under the second metal oxide layer.

11. The apparatus of claim 1, wherein the apparatus is part of a device package that includes device components located on the apparatus such that heat can be removed from the device components via heat transfer to a fluid circulating through the channels.

12. The apparatus of claim 11, wherein a plurality of the channels form an interconnecting network of looping channels laying in the vicinity of the device components.

13. The apparatus of claim 11, wherein the apparatus is located on a package substrate of the device package, wherein fluid delivery and fluid receiving conduits located on the package substrate are connected to the channels and to a fluid reservoir located on the package substrate.

14-20. (canceled)
